(19) United States
(12) Patent Application Publication
(10) Pub. No.: US 2026/0078526 A1
(43) Pub. Date: Mar. 19, 2026

(54) POLYCRYSTALLINE MATERIALS COMPRISING YTTRIUM ALUMINUM PEROVSKITE AND METHODS OF MAKING THE SAME

(71) Applicant: CoorsTek, Inc., Golden, CO (US)

(72) Inventors: Steven Landin, Conifer, CO (US); David Henry Hook, Lakewood, CO (US); Rebecca Mullen, Lakewood, CO (US)

(21) Appl. No.: 19/399,521

(22) Filed: Nov. 24, 2025

Related U.S. Application Data
(63) Continuation of application No. PCT/US2024/030475, filed on May 22, 2024.
(60) Provisional application No. 63/470,021, filed on May 31, 2023.

(51) Int. Cl. C30B 29/22; C30B 28/02

(52) U.S. Cl. CPC C30B 29/225; C30B 28/02

(57) ABSTRACT

New polycrystalline materials having yttrium aluminum perovskite (YAP) and yttrium zirconate (YZ) are described. In one aspect, a polycrystalline material (e.g., a bulk or monolithic polycrystalline material) may comprise (a) at least 50 wt. % yttrium aluminum perovskite (YAP) phase, and (b) at least 0.1 wt. % yttrium zirconate (YZ) phase. Such polycrystalline materials may realize an improved combination of properties, such as an improved combination of two or more of density, modulus of rupture (MOR), fracture toughness, dielectric strength, loss tangent, and plasma etch resistance, among others.

### CROSS-REFERENCE TO RELATED APPLICATION

This application is a continuation of International Patent Application No. PCT/US2024/030475, entitled “POLYCRYSTALLINE MATERIALS COMPRISING YTTRIUM ALUMINUM PEROVSKITE AND METHODS OF MAKING THE SAME,” filed May 22, 2024, which claims the benefit of U.S. Provisional Patent Application No. 63/470,021, entitled, “POLYCRYSTALLINE MATERIALS COMPRISING YTTRIUM ALUMINUM PEROVSKITE AND METHODS OF MAKING THE SAME,” filed on May 31, 2023. Each of the above-identified patent applications are hereby incorporated by reference in their entirety.

### BACKGROUND

As noted in U.S. Patent Application Publication No. 2021/0221742, ceramic materials can be used to form structures that are transparent to various wavelengths of electromagnetic radiation. However, certain ceramic materials may not have enough structural integrity to be exposed to extreme forces or temperatures. Additionally, where ceramic materials include multiple materials, mismatches in the refractive index of each material can affect the transmissivity and emittance of the ceramic material.

### SUMMARY OF THE DISCLOSURE

Broadly, the present patent application relates to new polycrystalline materials including yttrium aluminum perovskite (YAP) and yttrium zirconate (YZ) and methods of making the same. In one aspect, a polycrystalline material (e.g., a bulk or monolithic polycrystalline material) may comprise (a) at least 50 wt. % yttrium aluminum perovskite (YAP) phase, and (b) at least 0.1 wt. % yttrium zirconate (YZ) phase. Such polycrystalline materials may realize an improved combination of properties, such as an improved combination of two or more of density, modulus of rupture (MOR), fracture toughness, dielectric strength, loss tangent, and plasma etch resistance, among others. Additional details are provided below.

i. Polycrystalline Material Compositions

As noted above, the new polycrystalline materials generally comprise (and may consist of, or consist essentially of) (a) at least 50 wt. % yttrium aluminum perovskite (YAP) phase (YAlO₃), and (b) at least 0.1 wt. % yttrium zirconate (YZ) phase (Y₄,Zr₃O₁₂). As it relates to the YZ phase, in one embodiment, a new polycrystalline material includes at least 0.2 wt. % YZ phase. In another embodiment, a new polycrystalline material includes at least 0.3 wt. % YZ phase. In yet another embodiment, a new polycrystalline material includes at least 0.4 wt. % YZ phase. In another embodiment, a new polycrystalline material includes at least 0.5 wt. % YZ phase. In yet another embodiment, a new polycrystalline material includes at least 0.6 wt. % YZ phase. In another embodiment, a new polycrystalline material includes at least 0.7 wt. % YZ phase. In yet another embodiment, a new polycrystalline material includes at least 0.8 wt. % YZ phase. In another embodiment, a new polycrystalline material includes at least 0.9 wt. % YZ phase. In yet another embodiment, a new polycrystalline material includes at least 1.0 wt. % YZ phase. In another embodiment, a new polycrystalline material includes at least 1.2 wt. % YZ phase. In yet another embodiment, a new polycrystalline material includes at least 1.4 wt. % YZ phase. In another embodiment, a new polycrystalline material includes at least 1.6 wt. % YZ phase. In yet another embodiment, a new polycrystalline material includes at least 1.8 wt. % YZ phase. In another embodiment, a new polycrystalline material includes at least 2.0 wt. % YZ phase. In yet another embodiment, a new polycrystalline material includes at least 2.2 wt. % YZ phase. In another embodiment, a new polycrystalline material includes at least 2.4 wt. % YZ phase. In yet another embodiment, a new polycrystalline material includes at least 2.6 wt. % YZ phase. In another embodiment, a new polycrystalline material includes at least 2.8 wt. % YZ phase. In yet another embodiment, a new polycrystalline material includes at least 3.0 wt. % YZ phase.

In one embodiment, a new polycrystalline material includes not greater than 10.0 wt. % YZ phase. In another embodiment, a new polycrystalline material includes not greater than 9.0 wt. % YZ phase. In yet another embodiment, a new polycrystalline material includes not greater than 8.0 wt. % YZ phase. In another embodiment, a new polycrystalline material includes not greater than 7.0 wt. % YZ phase. In yet another embodiment, a new polycrystalline material includes not greater than 6.0 wt. % YZ phase. In another embodiment, a new polycrystalline material includes not greater than 5.0 wt. % YZ phase. In yet another embodiment, a new polycrystalline material includes not greater than 4.0 wt. % YZ phase. In another embodiment, a new polycrystalline material includes not greater than 3.0 wt. % YZ phase. In yet another embodiment, a new polycrystalline material includes not greater than 2.0 wt. % YZ phase. In another embodiment, a new polycrystalline material includes not greater than 1.0 wt. % YZ phase.

As noted above, the new polycrystalline materials generally include at least 50 wt. % yttrium aluminum perovskite (YAP) phase. In one embodiment, a new polycrystalline material includes at least 55 wt. % YAP phase. In another embodiment, a new polycrystalline material includes at least 60 wt. % YAP phase. In yet another embodiment, a new polycrystalline material includes at least 65 wt. % YAP phase. In another embodiment, a new polycrystalline material includes at least 70 wt. % YAP phase. In yet another embodiment, a new polycrystalline material includes at least 75 wt. % YAP phase. In another embodiment, a new polycrystalline material includes at least 80 wt. % YAP phase. In yet another embodiment, a new polycrystalline material includes at least 82 wt. % YAP phase. In another embodiment, a new polycrystalline material includes at least 84 wt. % YAP phase. In yet another embodiment, a new polycrystalline material includes at least 86 wt. % YAP phase. In another embodiment, a new polycrystalline material includes at least 88 wt. % YAP phase. In yet another embodiment, a new polycrystalline material includes at least 90 wt. % YAP phase. In another embodiment, a new polycrystalline material includes at least 92 wt. % YAP phase. In yet another embodiment, a new polycrystalline material includes at least 94 wt. % YAP phase. In another embodiment, a new polycrystalline material includes at least 95 wt. % YAP phase. In yet another embodiment, a new polycrystalline material includes at least 96 wt. % YAP phase. In another embodiment, a new polycrystalline material includes at least 97 wt. % YAP phase. In yet another embodiment, a new polycrystalline material includes at least 98 wt. % YAP phase. In another embodiment, a new polycrystalline material includes at least 99 wt. % YAP phase.

The new polycrystalline materials may include restricted amounts of other crystalline phases. For instance, the new polycrystalline materials may include restricted amounts of yttrium aluminum garnet (YAG) phase, yttrium aluminum monoclinic (YAM) phase, yttria phase, and alumina phase.

As it relates to yttrium aluminum garnet (YAG) phase (Y₃Al₅O₁₂), in one approach, a new polycrystalline material may include from 0.1 to 49.9 wt. % YAG phase. In one embodiment, a a new polycrystalline material comprises at least 1 wt. % YAG phase. In another embodiment, a new polycrystalline material includes at least 2 wt. % YAG phase. In yet another embodiment, a new polycrystalline material includes at least 3 wt. % YAG phase. In another embodiment, a new polycrystalline material includes at least 4 wt. % YAG phase. In yet another embodiment, a new polycrystalline material includes at least 5 wt. % YAG phase. In another embodiment, a new polycrystalline material includes at least 6 wt. % YAG phase. In yet another embodiment, a new polycrystalline material includes at least 7 wt. % YAG phase. In another embodiment, a new polycrystalline material includes at least 8 wt. % YAG phase. In yet another embodiment, a new polycrystalline material includes at least 9 wt. % YAG phase. In another embodiment, a new polycrystalline material includes at least 10 wt. % YAG phase. In yet another embodiment, a new polycrystalline material includes at least 11 wt. % YAG phase. In another embodiment, a new polycrystalline material includes at least 12 wt. % YAG phase. In yet another embodiment, a new polycrystalline material includes at least 13 wt. % YAG phase. In another embodiment, a new polycrystalline material includes at least 14 wt. % YAG phase. In yet another embodiment, a new polycrystalline material includes at least 15 wt. % YAG phase. In another embodiment, a new polycrystalline material includes at least 16 wt. % YAG phase. In yet another embodiment, a new polycrystalline material includes at least 17 wt. % YAG phase. In another embodiment, a new polycrystalline material includes at least 18 wt. % YAG phase. In yet another embodiment, a new polycrystalline material includes at least 19 wt. % YAG phase. In another embodiment, a new polycrystalline material includes at least 20 wt. % YAG phase. In yet another embodiment, a new polycrystalline material includes at least 21 wt. % YAG phase. In another embodiment, a new polycrystalline material includes at least 22 wt. % YAG phase. In yet another embodiment, a new polycrystalline material includes at least 23 wt. % YAG phase. In another embodiment, a new polycrystalline material includes at least 24 wt. % YAG phase.

In one embodiment, a new polycrystalline material includes not greater than 45 wt. % YAG phase. In another embodiment, a new polycrystalline material includes not greater than 40 wt. % YAG phase. In yet another embodiment, a new polycrystalline material includes not greater than 38 wt. % YAG phase. In another embodiment, a new polycrystalline material includes not greater than 36 wt. % YAG phase. In yet another embodiment, a new polycrystalline material includes not greater than 34 wt. % YAG phase. In another embodiment, a new polycrystalline material includes not greater than 32 wt. % YAG phase. In yet another embodiment, a new polycrystalline material includes not greater than 30 wt. % YAG phase. In another embodiment, a new polycrystalline material includes not greater than 28 wt. % YAG phase. In yet another embodiment, a new polycrystalline material includes not greater than 26 wt. % YAG phase. In another embodiment, a new polycrystalline material includes not greater than 24 wt. % YAG phase. In yet another embodiment, a new polycrystalline material includes not greater than 22 wt. % YAG phase. In another embodiment, a new polycrystalline material includes not greater than 20 wt. % YAG phase. In another embodiment, a new polycrystalline material includes not greater than 18 wt. % YAG phase. In yet another embodiment, a new polycrystalline material includes not greater than 16 wt. % YAG phase. In another embodiment, a new polycrystalline material includes not greater than 14 wt. % YAG phase. In yet another embodiment, a new polycrystalline material includes not greater than 12 wt. % YAG phase. In another embodiment, a new polycrystalline material includes not greater than 10 wt. % YAG phase. In yet another embodiment, a new polycrystalline material includes not greater than 8 wt. % YAG phase. In another embodiment, a new polycrystalline material includes not greater than 6 wt. % YAG phase. In yet another embodiment, a new polycrystalline material includes not greater than 5 wt. % YAG phase. In another embodiment, a new polycrystalline material includes not greater than 4 wt. % YAG phase. In yet another embodiment, a new polycrystalline material includes not greater than 3 wt. % YAG phase. In another embodiment, a new polycrystalline material includes not greater than 2 wt. % YAG phase. In yet another embodiment, a new polycrystalline material includes not greater than 1 wt. % YAG phase. In another embodiment, a new polycrystalline material includes not greater than 0.5 wt. % YAG phase.

In one approach, YAG phase is included in a new polycrystalline material as an impurity only.

As it relates to yttrium aluminum monoclinic (YAM) phase (Y₄Al₂O₉), in one embodiment, a new polycrystalline material includes not greater than 45 wt. % YAM phase. In another embodiment, a new polycrystalline material includes not greater than 40 wt. % YAM phase. In yet another embodiment, a new polycrystalline material includes not greater than 38 wt. % YAM phase. In another embodiment, a new polycrystalline material includes not greater than 36 wt. % YAM phase. In yet another embodiment, a new polycrystalline material includes not greater than 34 wt. % YAM phase. In another embodiment, a new polycrystalline material includes not greater than 32 wt. % YAM phase. In yet another embodiment, a new polycrystalline material includes not greater than 30 wt. % YAM phase. In another embodiment, a new polycrystalline material includes not greater than 28 wt. % YAM phase. In yet another embodiment, a new polycrystalline material includes not greater than 26 wt. % YAM phase. In another embodiment, a new polycrystalline material includes not greater than 24 wt. % YAM phase. In yet another embodiment, a new polycrystalline material includes not greater than 22 wt. % YAM phase. In another embodiment, a new polycrystalline material includes not greater than 20 wt. % YAM phase. In another embodiment, a new polycrystalline material includes not greater than 18 wt. % YAM phase. In yet another embodiment, a new polycrystalline material includes not greater than 16 wt. % YAM phase. In another embodiment, a new polycrystalline material includes not greater than 14 wt. % YAM phase. In yet another embodiment, a new polycrystalline material includes not greater than 12 wt. % YAM phase. In another embodiment, a new polycrystalline material includes not greater than 10 wt. % YAM phase. In yet another embodiment, a new polycrystalline material includes not greater than 8 wt. % YAM phase. In another embodiment, a new polycrystalline material includes not greater than 6 wt. % YAM phase. In yet another embodiment, a new polycrystalline material includes not greater than 5 wt. % YAM phase. In another embodiment, a new polycrystalline material includes not greater than 4 wt. % YAM phase. In yet another embodiment, a new polycrystalline material includes not greater than 3 wt. % YAM phase. In another embodiment, a new polycrystalline material includes not greater than 2 wt. % YAM phase. In yet another embodiment, a new polycrystalline material includes not greater than 1 wt. % YAM phase. In another embodiment, a new polycrystalline material includes not greater than 0.5 wt. % YAM phase.

In one approach, YAM phase is included in a new polycrystalline material as an impurity only.

As noted above, the new polycrystalline materials may include restricted amounts of yttria (Y₂O₃) phase. In one embodiment, a new polycrystalline material includes not greater than 10 wt. % yttria phase. In another embodiment, a new polycrystalline material includes not greater than 8 wt. % yttria phase. In yet another embodiment, a new polycrystalline material includes not greater than 6 wt. % yttria phase. In another embodiment, a new polycrystalline material includes not greater than 5 wt. % yttria phase. In yet another embodiment, a new polycrystalline material includes not greater than 4 wt. % yttria phase. In another embodiment, a new polycrystalline material includes not greater than 3 wt. % yttria phase. In yet another embodiment, a new polycrystalline material includes not greater than 2 wt. % yttria phase. In another embodiment, a new polycrystalline material includes not greater than 1 wt. % yttria phase. In yet another embodiment, a new polycrystalline material includes not greater than 0.5 wt. % yttria phase. In another embodiment, a new polycrystalline material includes not greater than 0.25 wt. % yttria phase. In yet another embodiment, a new polycrystalline material includes not greater than 0.1 wt. % yttria phase.

In one approach, yttria phase is included in a new polycrystalline material as an impurity only.

As noted above, the new polycrystalline materials may include restricted amounts of alumina (Al₂O₃) phase. In one embodiment, a new polycrystalline material includes not greater than 10 wt. % alumina phase. In another embodiment, a new polycrystalline material includes not greater than 8 wt. % alumina phase. In yet another embodiment, a new polycrystalline material includes not greater than 6 wt. % alumina phase. In another embodiment, a new polycrystalline material includes not greater than 5 wt. % alumina phase. In yet another embodiment, a new polycrystalline material includes not greater than 4 wt. % alumina phase. In another embodiment, a new polycrystalline material includes not greater than 3 wt. % alumina phase. In yet another embodiment, a new polycrystalline material includes not greater than 2 wt. % alumina phase. In another embodiment, a new polycrystalline material includes not greater than 1 wt. % alumina phase. In yet another embodiment, a new polycrystalline material includes not greater than 0.5 wt. % alumina phase. In another embodiment, a new polycrystalline material includes not greater than 0.25 wt. % alumina phase. In yet another embodiment, a new polycrystalline material includes not greater than 0.1 wt. % alumina phase.

In one approach, alumina phase is included in a new polycrystalline material as an impurity only.

ii. Microstructure

As noted above the new polycrystalline materials may realize an improved combination of properties, such as an improved combination of two or more of density, modulus of rupture (MOR), fracture toughness, dielectric strength, loss tangent, and plasma etch resistance, among others. Such properties may be realized due to, for instance, the unique microstructure of the new polycrystalline materials.

In one embodiment, a new polycrystalline material realizes an average grain size of not greater than 30 micrometers. In another embodiment, a new polycrystalline material realizes an average grain size of not greater than 28 micrometers. In yet another embodiment, a new polycrystalline material realizes an average grain size of not greater than 26 micrometers. In another embodiment, a new polycrystalline material realizes an average grain size of not greater than 24 micrometers. In yet another embodiment, a new polycrystalline material realizes an average grain size of not greater than 22 micrometers. In another embodiment, a new polycrystalline material realizes an average grain size of not greater than 20 micrometers. In yet another embodiment, a new polycrystalline material realizes an average grain size of not greater than 18 micrometers. In another embodiment, a new polycrystalline material realizes an average grain size of not greater than 16 micrometers. In yet another embodiment, a new polycrystalline material realizes an average grain size of not greater than 14 micrometers. In another embodiment, a new polycrystalline material realizes an average grain size of not greater than 12 micrometers. In yet another embodiment, a new polycrystalline material realizes an average grain size of not greater than 10 micrometers. In another embodiment, a new polycrystalline material realizes an average grain size of not greater than 8 micrometers. In yet another embodiment, a new polycrystalline material realizes an average grain size of not greater than 6 micrometers. In another embodiment, a new polycrystalline material realizes an average grain size of not greater than 5 micrometers. In yet another embodiment, a new polycrystalline material realizes an average grain size of not greater than 4 micrometers. In another embodiment, a new polycrystalline material realizes an average grain size of not greater than 3 micrometers. In yet another embodiment, a new polycrystalline material realizes an average grain size of not greater than 2 micrometers.

In one embodiment, a new polycrystalline material realizes a maximum grain size of not greater than 80 micrometers. In another embodiment, a new polycrystalline material realizes a maximum grain size of not greater than 70 micrometers. In yet another embodiment, a new polycrystalline material realizes a maximum grain size of not greater than 60 micrometers. In another embodiment, a new polycrystalline material realizes a maximum grain size of not greater than 50 micrometers. In yet another embodiment, a new polycrystalline material realizes a maximum grain size of not greater than 40 micrometers. In another embodiment, a new polycrystalline material realizes a maximum grain size of not greater than 30 micrometers. In yet another embodiment, a new polycrystalline material realizes a maximum grain size of not greater than 25 micrometers. In another embodiment, a new polycrystalline material realizes a maximum grain size of not greater than 20 micrometers. In yet another embodiment, a new polycrystalline material realizes a maximum grain size of not greater than 18 micrometers. In another embodiment, a new polycrystalline material realizes a maximum grain size of not greater than 16 micrometers. In yet another embodiment, a new polycrystalline material realizes a maximum grain size of not greater than 14 micrometers. In another embodiment, a new polycrystalline material realizes a maximum grain size of not greater than 12 micrometers. In yet another embodiment, a new polycrystalline material realizes a maximum grain size of not greater than 10 micrometers. In another embodiment, a new polycrystalline material realizes a maximum grain size of not greater than 9 micrometers. In yet another embodiment, a new polycrystalline material realizes a maximum grain size of not greater than 8 micrometers. In another embodiment, a new polycrystalline material realizes a maximum grain size of not greater than 7 micrometers. In yet another embodiment, a new polycrystalline material realizes a maximum grain size of not greater than 6 micrometers.

In one embodiment, a new polycrystalline material comprises at least some YZ phase precipitates at the grain boundaries.

iii. Methods of Manufacture

The new polycrystalline materials may be produced in a variety of manners, including by ceramic powder processing techniques. In one embodiment, and referring now to FIG. 1, a method (10) may include the steps of producing a green body from a powder comprising YAP (YAlO₃) and YZ (yttrium zirconate) (100), and sintering the green body, thereby forming a final product (200). The final product may realize any of the compositions described in the Polycrystalline Material Compositions section (Section i), above.

As it relates to step (100), i.e., producing a green body, this step may include any suitable green body manufacturing method, including, without limitation, die compaction, isostatic pressing, slip casting, tape casting, extrusion and injection molding, among others. In one embodiment, the producing step (100) is die compaction (e.g., dry pressing to form a solid compact).

As it relates to step (200), i.e., sintering the green body, this step may include heating the green body at any temperature, or series of temperatures, sufficient to produce a densified final product. In one embodiment, the sintering temperature is from 1200° to 1900° C. In one embodiment, the sintering time is from 0.2 hours to 20 hours. In one embodiment, the sintering is pressureless sintering. In another embodiment, pressure may be applied during sintering.

In one embodiment, and referring now to FIG. 2, a method (10′) may include the steps of preparing a precursor powder (20) and then producing a powder comprising YAP (YAlO₃) and YZ (yttrium zirconate) phases from the precursor powder (50). The powder comprising the YAP (YAlO₃) and YZ (yttrium zirconate) phases may then be used to produce the green body, as described previously.

As it relates to preparing the precursor powder step (20), a method (10′) may include blending yttria and alumina to prepare a powder blend (22), and heating the powder blend at a temperature and for a time sufficient to produce the precursor powder (24). As it relates to the blending step (22), the powder blend may comprise from 45-50 mol. % yttria and 50-55 mol. % alumina, but other amounts may be used. As shown by the examples herein, the amounts of yttria and alumina may be preselected to achieve predetermined amounts of desired crystalline phases (e.g., predetermined amounts of YAP, YAG, YAM, YZ, yttria and/or alumina phases).

In one embodiment, a precursor powder includes at least 55 wt. % YAP phase. In another embodiment, a precursor powder includes at least 60 wt. % YAP phase. In yet another embodiment, a precursor powder includes at least 65 wt. % YAP phase. In another embodiment, a precursor powder includes at least 70 wt. % YAP phase. In yet another embodiment, a precursor powder includes at least 75 wt. % YAP phase. In another embodiment, a precursor powder includes at least 80 wt. % YAP phase. In yet another embodiment, a precursor powder includes at least 82 wt. % YAP phase. In another embodiment, a precursor powder includes at least 84 wt. % YAP phase. In yet another embodiment, a precursor powder includes at least 86 wt. % YAP phase. In another embodiment, a precursor powder includes at least 88 wt. % YAP phase. In yet another embodiment, a precursor powder includes at least 90 wt. % YAP phase. In another embodiment, a precursor powder includes at least 92 wt. % YAP phase. In yet another embodiment, a precursor powder includes at least 94 wt. % YAP phase. In another embodiment, a precursor powder includes at least 95 wt. % YAP phase. In yet another embodiment, a precursor powder includes at least 96 wt. % YAP phase. In another embodiment, a precursor powder includes at least 97 wt. % YAP phase. In yet another embodiment, a precursor powder includes at least 98 wt. % YAP phase. In another embodiment, a precursor powder includes at least 99 wt. % YAP phase.

In one embodiment, a precursor powder includes not greater than 50 wt. % YAG phase. In another embodiment, a precursor powder includes not greater than 45 wt. % YAG phase. In yet another embodiment, a precursor powder includes not greater than 40 wt. % YAG phase. In another embodiment, a precursor powder includes not greater than 35 wt. % YAG phase. In yet another embodiment, a precursor powder includes not greater than 30 wt. % YAG phase. In another embodiment, a precursor powder includes not greater than 25 wt. % YAG phase. In yet another embodiment, a precursor powder includes not greater than 20 wt. % YAG phase. In another embodiment, a precursor powder includes not greater than 15 wt. % YAG phase. In yet another embodiment, a precursor powder includes not greater than 10 wt. % YAG phase. In another embodiment, a precursor powder includes not greater than 5 wt. % YAG phase. In yet another embodiment, a precursor powder includes not greater than 3 wt. % YAG phase. In another embodiment, a precursor powder includes not greater than 1 wt. % YAG phase. In yet another embodiment, a precursor powder includes not greater than 0.5 wt. % YAG phase. In another embodiment, a precursor powder includes not greater than 0.25 wt. % YAG phase. In yet another embodiment, a precursor powder includes not greater than 0.1 wt. % YAG phase.

In some embodiments, purposeful amounts of YAG phase is included in the precursor powder. For instance, in one embodiment, a precursor powder may include at least 0.5 wt. % YAG phase. In another embodiment, a precursor powder may include at least 1 wt. % YAG phase.

In one embodiment, a precursor powder includes not greater than 50 wt. % YAM phase. In another embodiment, a precursor powder includes not greater than 45 wt. % YAM phase. In yet another embodiment, a precursor powder includes not greater than 40 wt. % YAM phase. In another embodiment, a precursor powder includes not greater than 35 wt. % YAM phase. In yet another embodiment, a precursor powder includes not greater than 30 wt. % YAM phase. In another embodiment, a precursor powder includes not greater than 25 wt. % YAM phase. In yet another embodiment, a precursor powder includes not greater than 20 wt. % YAM phase. In another embodiment, a precursor powder includes not greater than 15 wt. % YAM phase. In yet another embodiment, a precursor powder includes not greater than 10 wt. % YAM phase. In another embodiment, a precursor powder includes not greater than 5 wt. % YAM phase. In yet another embodiment, a precursor powder includes not greater than 3 wt. % YAM phase. In another embodiment, a precursor powder includes not greater than 1 wt. % YAM phase. In yet another embodiment, a precursor powder includes not greater than 0.5 wt. % YAM phase. In another embodiment, a precursor powder includes not greater than 0.25 wt. % YAM phase. In yet another embodiment, a precursor powder includes not greater than 0.1 wt. % YAM phase.

In some embodiments, purposeful amounts of YAM phase is included in the precursor powder. For instance, in one embodiment, a precursor powder may include at least 0.5 wt. % YAM phase. In another embodiment, a precursor powder may include at least 1 wt. % YAM phase.

In one embodiment, a precursor powder includes not greater than 10 wt. % yttria phase. In another embodiment, a precursor powder includes not greater than 8 wt. % yttria phase. In yet another embodiment, a precursor powder includes not greater than 6 wt. % yttria phase. In another embodiment, a precursor powder includes not greater than 5 wt. % yttria phase. In yet another embodiment, a precursor powder includes not greater than 4 wt. % yttria phase. In another embodiment, a precursor powder includes not greater than 3 wt. % yttria phase. In yet another embodiment, a precursor powder includes not greater than 2 wt. % yttria phase. In another embodiment, a precursor powder includes not greater than 1 wt. % yttria phase. In yet another embodiment, a precursor powder includes not greater than 0.5 wt. % yttria phase. In another embodiment, a precursor powder includes not greater than 0.25 wt. % yttria phase. In yet another embodiment, a precursor powder includes not greater than 0.1 wt. % yttria phase.

In one embodiment, a precursor powder includes not greater than 10 wt. % alumina phase. In another embodiment, a precursor powder includes not greater than 8 wt. % alumina phase. In yet another embodiment, a precursor powder includes not greater than 6 wt. % alumina phase. In another embodiment, a precursor powder includes not greater than 5 wt. % alumina phase. In yet another embodiment, a precursor powder includes not greater than 4 wt. % alumina phase. In another embodiment, a precursor powder includes not greater than 3 wt. % alumina phase. In yet another embodiment, a precursor powder includes not greater than 2 wt. % alumina phase. In another embodiment, a precursor powder includes not greater than 1 wt. % alumina phase. In yet another embodiment, a precursor powder includes not greater than 0.5 wt. % alumina phase. In another embodiment, a precursor powder includes not greater than 0.25 wt. % alumina phase. In yet another embodiment, a precursor powder includes not greater than 0.1 wt. % alumina phase.

Referring back to FIG. 2, the step of producing the precursor powder step (20) may include one or more additional powder processing steps, such as any one of (a) milling of the powder blend (e.g., attrition milling), (b) screening of the powder blend, (c) preparing the powder blend for spray drying (e.g., using appropriate binders), and (d) spray drying of the blended powder. The heating step (24) may follow the spray drying step.

With continued reference to FIG. 2, the step of producing a powder comprising YAP (YAlO₃) and YZ (yttrium zirconate) phases from the precursor powder (50) may include any suitable powder processing steps, such as any one of (a) milling of the precursor powder (e.g., attrition milling), (b) screening of the precursor powder, (c) preparing the precursor for spray drying (e.g., using appropriate binders), and (d) spray drying of the precursor powder to produce a final powder comprising YAP (YAlO₃) and YZ (yttrium zirconate) phases. The final powder may then be used to produce a green body, as previously described.

In one approach, and referring now to FIG. 3, a method (10″) may include the step of introducing zirconium (52) to facilitate production of YZ phase in the final powder. Zirconium may be introduced at any suitable point in the process of producing the final powder. For instance, zirconium may be introduced during milling (54) of the precursor powder, such as by milling with a zirconium-containing milling media (e.g., zirconia milling powder). In such embodiments, the zirconium-containing media may be considered a transfer material.

In some embodiments, zirconium may be introduced by adding a zirconium-containing material (56), such a zirconium-containing powder, to the precursor powder. For instance, a zirconium-containing powder (e.g., a zirconia powder) may be blended with the precursor powder to facilitate introduction of zirconium. Such blending may occur, for instance, prior to, during, or after milling of the precursor powder.

In some embodiments, zirconium may be introduced by exposing the precursor powder to a liquid comprising zirconium (58). For instance, the precursor powder may be contacted with or by an aqueous or organic solution comprising zirconium (e.g., zirconium ions). Such contacting may occur, for instance, in preparing the precursor powder for spray drying.

The amount of zirconium introduced to the precursor powder may be selected based on the desired amount of YZ phase in the final powder.

Zirconium may also or alternatively be introduced during production of the precursor powder. For instance, and referred now to FIG. 2, zirconium may be introduced during (i) blending of the yttria and alumina powders (22) or (ii) milling of the yttria and alumina powders (e.g., by milling with a zirconium-containing milling media). Zirconium may also or alternatively be introduced in preparing the powder blend for spray drying, such as by contacting the powder blend with an aqueous or organic solution comprising zirconium (e.g., zirconium ions).

The amount of zirconium introduced to the powder blend may be selected based on the desired amount of YZ phase in the final powder.

iv. Properties

As noted above, the new polycrystalline materials may realize an improved combination of properties, such as an improved combination of two or more of density, modulus of rupture (MOR), fracture toughness, dielectric strength, loss tangent, and plasma etch resistance, among others.

In one embodiment, a new polycrystalline material realizes a density of at least 4.5 g/cm³. In another embodiment, a new polycrystalline material realizes a density of at least 4.6 g/cm³. In yet another embodiment, a new polycrystalline material realizes a density of at least 4.7 g/cm³. In another embodiment, a new polycrystalline material realizes a density of at least 4.8 g/cm³. In yet another embodiment, a new polycrystalline material realizes a density of at least 4.9 g/cm³. In another embodiment, a new polycrystalline material realizes a density of at least 5.0 g/cm³. In yet another embodiment, a new polycrystalline material realizes a density of at least 5.05 g/cm³. In another embodiment, a new polycrystalline material realizes a density of at least 5.10 g/cm³. In yet another embodiment, a new polycrystalline material realizes a density of at least 5.15 g/cm³. In another embodiment, a new polycrystalline material realizes a density of at least 5.20 g/cm³. In yet another embodiment, a new polycrystalline material realizes a density of at least 5.22 g/cm³. In another embodiment, a new polycrystalline material realizes a density of at least 5.24 g/cm³. In yet another embodiment, a new polycrystalline material realizes a density of at least 5.26 g/cm³. In another embodiment, a new polycrystalline material realizes a density of at least 5.28 g/cm³. In yet another embodiment, a new polycrystalline material realizes a density of at least 5.30 g/cm³.

In one embodiment, a new polycrystalline material realizes an MOR (4-pt) strength of at least 200 MPa. In another embodiment, a new polycrystalline material realizes an MOR (4-pt) strength of at least 210 MPa. In yet another embodiment, a new polycrystalline material realizes an MOR (4-pt) strength of at least 220 MPa. In another embodiment, a new polycrystalline material realizes an MOR (4-pt) strength of at least 230 MPa. In yet another embodiment, a new polycrystalline material realizes an MOR (4-pt) strength of at least 240 MPa. In another embodiment, a new polycrystalline material realizes an MOR (4-pt) strength of at least 250 MPa. In yet another embodiment, a new polycrystalline material realizes an MOR (4-pt) strength of at least 260 MPa. In another embodiment, a new polycrystalline material realizes an MOR (4-pt) strength of at least 270 MPa. In yet another embodiment, a new polycrystalline material realizes an MOR (4-pt) strength of at least 280 MPa. In another embodiment, a new polycrystalline material realizes an MOR (4-pt) strength of at least 290 MPa. In yet another embodiment, a new polycrystalline material realizes an MOR (4-pt) strength of at least 300 MPa. In another embodiment, a new polycrystalline material realizes an MOR (4-pt) strength of at least 310 MPa. In yet another embodiment, a new polycrystalline material realizes an MOR (4-pt) strength of at least 320 MPa. In another embodiment, a new polycrystalline material realizes an MOR (4-pt) strength of at least 330 MPa. In yet another embodiment, a new polycrystalline material realizes an MOR (4-pt) strength of at least 340 MPa. In another embodiment, a new polycrystalline material realizes an MOR (4-pt) strength of at least 350 MPa. In yet another embodiment, a new polycrystalline material realizes an MOR (4-pt) strength of at least 360 MPa. In another embodiment, a new polycrystalline material realizes an MOR (4-pt) strength of at least 370 MPa. In yet another embodiment, a new polycrystalline material realizes an MOR (4-pt) strength of at least 380 MPa. In another embodiment, a new polycrystalline material realizes an MOR (4-pt) strength of at least 390 MPa.

In one embodiment, a new polycrystalline material realizes a plane strain (K_{IC}) fracture toughness of at least 2.0 MPa*m^{1/2}. In another embodiment, a new polycrystalline material realizes a plane strain (K_{IC}) fracture toughness of at least 2.2 MPa*m^{1/2}. In yet another embodiment, a new polycrystalline material realizes a plane strain (K_{IC}) fracture toughness of at least 2.4 MPa*m^{1/2}. In another embodiment, a new polycrystalline material realizes a plane strain (K_{IC}) fracture toughness of at least 2.6 MPa*m^{1/2}. In yet another embodiment, a new polycrystalline material realizes a plane strain (K_{IC}) fracture toughness of at least 2.8 MPa*m^{1/2}. In another embodiment, a new polycrystalline material realizes a plane strain (K_{IC}) fracture toughness of at least 3.0 MPa*m^{1/2}. In yet another embodiment, a new polycrystalline material realizes a plane strain (K_{IC}) fracture toughness of at least 3.2 MPa*m^{1/2}. In another embodiment, a new polycrystalline material realizes a plane strain (K_{IC}) fracture toughness of at least 3.4 MPa*m^{1/2}. In yet another embodiment, a new polycrystalline material realizes a plane strain (K_{IC}) fracture toughness of at least 3.6 MPa*m^{1/2}. In another embodiment, a new polycrystalline material realizes a plane strain (K_{IC}) fracture toughness of at least 3.8 MPa*m^{1/2}. In yet another embodiment, a new polycrystalline material realizes a plane strain (K_{IC}) fracture toughness of at least 4.0 MPa*m^{1/2}. In another embodiment, a new polycrystalline material realizes a plane strain (K_{IC}) fracture toughness of at least 4.2 MPa*m^{1/2}. In yet another embodiment, a new polycrystalline material realizes a plane strain (K_{IC}) fracture toughness of at least 4.4 MPa*m^{1/2}. In another embodiment, a new polycrystalline material realizes a plane strain (K_{IC}) fracture toughness of at least 4.5 MPa*m^{1/2}. In yet another embodiment, a new polycrystalline material realizes a plane strain (Kc) fracture toughness of at least 4.6 MPa*m^{1/2}. In another embodiment, a new polycrystalline material realizes a plane strain (K_{IC}) fracture toughness of at least 4.7 MPa*m^{1/2}. In yet another embodiment, a new polycrystalline material realizes a plane strain (K_{IC}) fracture toughness of at least 4.8 MPa*m^{1/2}. In another embodiment, a new polycrystalline material realizes a plane strain (K_{IC}) fracture toughness of at least 4.9 MPa*m^{1/2}. In yet another embodiment, a new polycrystalline material realizes a plane strain (K_{IC}) fracture toughness of at least 5.0 MPa*m^{1/2}. In another embodiment, a new polycrystalline material realizes a plane strain (K_{IC}) fracture toughness of at least 5.1 MPa*m^{1/2}. In yet another embodiment, a new polycrystalline material realizes a plane strain (K_{IC}) fracture toughness of at least 5.2 MPa*m^{1/2}. In another embodiment, a new polycrystalline material realizes a plane strain (K_{IC}) fracture toughness of at least 5.3 MPa*m^{1/2}.

In one embodiment, a new polycrystalline material realizes an AC dielectric strength (1 mm) of at least 12.0 KV/mm. In another embodiment, a new polycrystalline material realizes an AC dielectric strength (1 mm) of at least 12.2 KV/mm. In yet another embodiment, a new polycrystalline material realizes an AC dielectric strength (1 mm) of at least 12.4 KV/mm. In another embodiment, a new polycrystalline material realizes an AC dielectric strength (1 mm) of at least 12.6 KV/mm. In yet another embodiment, a new polycrystalline material realizes an AC dielectric strength (1 mm) of at least 12.8 KV/mm. In another embodiment, a new polycrystalline material realizes an AC dielectric strength (1 mm) of at least 13.0 KV/mm. In yet another embodiment, a new polycrystalline material realizes an AC dielectric strength (1 mm) of at least 13.2 KV/mm. In another embodiment, a new polycrystalline material realizes an AC dielectric strength (1 mm) of at least 13.4 KV/mm. In yet another embodiment, a new polycrystalline material realizes an AC dielectric strength (1 mm) of at least 13.6 KV/mm. In another embodiment, a new polycrystalline material realizes an AC dielectric strength (1 mm) of at least 13.8 KV/mm. In yet another embodiment, a new polycrystalline material realizes an AC dielectric strength (1 mm) of at least 14.0 KV/mm. In another embodiment, a new polycrystalline material realizes an AC dielectric strength (1 mm) of at least 14.2 KV/mm. In yet another embodiment, a new polycrystalline material realizes an AC dielectric strength (1 mm) of at least 14.3 KV/mm. In another embodiment, a new polycrystalline material realizes an AC dielectric strength (1 mm) of at least 14.4 KV/mm. In yet another embodiment, a new polycrystalline material realizes an AC dielectric strength (1 mm) of at least 14.5 KV/mm. In another embodiment, a new polycrystalline material realizes an AC dielectric strength (1 mm) of at least 14.6 KV/mm. In yet another embodiment, a new polycrystalline material realizes an AC dielectric strength (1 mm) of at least 14.7 KV/mm. In another embodiment, a new polycrystalline material realizes an AC dielectric strength (1 mm) of at least 14.8 KV/mm. In yet another embodiment, a new polycrystalline material realizes an AC dielectric strength (1 mm) of at least 14.9 KV/mm. In another embodiment, a new polycrystalline material realizes an AC dielectric strength (1 mm) of at least 15.0 KV/mm. In yet another embodiment, a new polycrystalline material realizes an AC dielectric strength (1 mm) of at least 15.1 KV/mm. In another embodiment, a new polycrystalline material realizes an AC dielectric strength (1 mm) of at least 15.2 KV/mm. In yet another embodiment, a new polycrystalline material realizes an AC dielectric strength (1 mm) of at least 15.3 KV/mm. In another embodiment, a new polycrystalline material realizes an AC dielectric strength (1 mm) of at least 15.4 KV/mm. In yet another embodiment, a new polycrystalline material realizes an AC dielectric strength (1 mm) of at least 15.5 KV/mm. In another embodiment, a new polycrystalline material realizes an AC dielectric strength (1 mm) of at least 15.6 KV/mm.

In one embodiment, a new polycrystalline material realizes a dielectric constant (4 GHz) of at least 12.0. In another embodiment, a new polycrystalline material realizes a dielectric constant (4 GHz) of at least 12.2. In yet another embodiment, a new polycrystalline material realizes a dielectric constant (4 GHZ) of at least 12.4. In another embodiment, a new polycrystalline material realizes a dielectric constant (4 GHZ) of at least 12.6. In yet another embodiment, a new polycrystalline material realizes a dielectric constant (4 GHZ) of at least 12.8. In another embodiment, a new polycrystalline material realizes a dielectric constant (4 GHz) of at least 13.0. In yet another embodiment, a new polycrystalline material realizes a dielectric constant (4 GHZ) of at least 13.2. In another embodiment, a new polycrystalline material realizes a dielectric constant (4 GHz) of at least 13.4. In yet another embodiment, a new polycrystalline material realizes a dielectric constant (4 GHZ) of at least 13.6. In another embodiment, a new polycrystalline material realizes a dielectric constant (4 GHZ) of at least 13.8. In yet another embodiment, a new polycrystalline material realizes a dielectric constant (4 GHZ) of at least 14.0. In another embodiment, a new polycrystalline material realizes a dielectric constant (4 GHz) of at least 14.2. In yet another embodiment, a new polycrystalline material realizes a dielectric constant (4 GHZ) of at least 14.3. In another embodiment, a new polycrystalline material realizes a dielectric constant (4 GHZ) of at least 14.4. In yet another embodiment, a new polycrystalline material realizes a dielectric constant (4 GHZ) of at least 14.5. In another embodiment, a new polycrystalline material realizes a dielectric constant (4 GHZ) of at least 14.6. In yet another embodiment, a new polycrystalline material realizes a dielectric constant (4 GHZ) of at least 14.7. In another embodiment, a new polycrystalline material realizes a dielectric constant (4 GHz) of at least 14.8. In yet another embodiment, a new polycrystalline material realizes a dielectric constant (4 GHZ) of at least 14.9. In another embodiment, a new polycrystalline material realizes a dielectric constant (4 GHz) of at least 15.0. In yet another embodiment, a new polycrystalline material realizes a dielectric constant (4 GHZ) of at least 15.1. In another embodiment, a new polycrystalline material realizes a dielectric constant (4 GHz) of at least 15.2. In yet another embodiment, a new polycrystalline material realizes a dielectric constant (4 GHZ) of at least 15.3. In another embodiment, a new polycrystalline material realizes a dielectric constant (4 GHz) of at least 15.4. In yet another embodiment, a new polycrystalline material realizes a dielectric constant (4 GHz) of at least 15.5. In another embodiment, a new polycrystalline material realizes a dielectric constant (4 GHZ) of at least 15.6. In yet another embodiment, a new polycrystalline material realizes a dielectric constant (4 GHZ) of at least 15.7.

In one embodiment, a new polycrystalline material realizes a loss tangent (4 GHz) of not greater than 5.0×10⁻⁴. In another embodiment, a new polycrystalline material realizes a loss tangent (4 GHZ) of not greater than 4.0×10⁻⁴. In yet another embodiment, a new polycrystalline material realizes a loss tangent (4 GHZ) of not greater than 3.0×10⁻⁴. In another embodiment, a new polycrystalline material realizes a loss tangent (4 GHZ) of not greater than 2.0×10⁻⁴. In yet another embodiment, a new polycrystalline material realizes a loss tangent (4 GHz) of not greater than 1.0×10⁻⁴. In another embodiment, a new polycrystalline material realizes a loss tangent (4 GHz) of not greater than 9.0×10⁻⁵. In yet another embodiment, a new polycrystalline material realizes a loss tangent (4 GHz) of not greater than 8.0×10⁻⁵. In another embodiment, a new polycrystalline material realizes a loss tangent (4 GHz) of not greater than 7.0×10⁻⁵. In yet another embodiment, a new polycrystalline material realizes a loss tangent (4 GHz) of not greater than 6.0×10⁻⁵. In another embodiment, a new polycrystalline material realizes a loss tangent (4 GHz) of not greater than 5.0×10⁻⁵. In yet another embodiment, a new polycrystalline material realizes a loss tangent (4 GHz) of not greater than 4.0×10⁻⁵. In another embodiment, a new polycrystalline material realizes a loss tangent (4 GHz) of not greater than 3.0×10⁻⁵. In yet another embodiment, a new polycrystalline material realizes a loss tangent (4 GHz) of not greater than 2.0×10⁻⁵.

In one approach, a new polycrystalline material realizes resistance to plasma etching. In one embodiment, a new polycrystalline material realizes a bulk etch rate of not greater than 0.07 micrometers per hour when tested in accordance with the etch rate testing procedure explained in the Materials Characterization section herein. In another embodiment, a new polycrystalline material realizes a bulk etch rate of not greater than 0.06 micrometers per hour. In yet another embodiment, a new polycrystalline material realizes a bulk etch rate of not greater than 0.05 micrometers per hour. In another embodiment, a new polycrystalline material realizes a bulk etch rate of not greater than 0.04 micrometers per hour. In yet another embodiment, a new polycrystalline material realizes a bulk etch rate of not greater than 0.03 micrometers per hour. In another embodiment, a new polycrystalline material realizes a bulk etch rate of not greater than 0.02 micrometers per hour. In yet another embodiment, a new polycrystalline material realizes a bulk etch rate of not greater than 0.01 micrometers per hour.

As shown in the Examples, the new materials may realize a unique color. In some embodiments, the polycrystalline material realizes the color white in the as-sintered condition. In some embodiments, the polycrystalline material is translucent in the as-sintered condition. Such color properties may provide improved aesthetics.

v. Product Form and Applications

The new polycrystalline materials may take on a variety of product forms and may be used in a variety of industrial applications. In one embodiment, a new polycrystalline material is a bulk (monolithic) polycrystalline material. In one embodiment, a new polycrystalline material is used in a semiconductor processing application. In one embodiment, a new polycrystalline material is in the form of a semiconductor component. In one embodiment, the semiconductor component is in the form of a nozzle blank or a nozzle. In one embodiment, the semiconductor component is configured for use in a plasma environment.

vi. Material Characterization

As noted above, x-ray diffraction (XRD) may be used to determine the amount of crystalline phases of the polycrystalline materials described herein. The XRD instrument should be a Bruker D8 Discover (Bruker Corp., 40 Manning Rd, Billerica, MA 01821) or comparable XRD instrument. The XRD radiation should be copper K-alpha radiation. The power should be 1.6 kW. The scan range should be 20° to 70° (2 theta) (d=4.5 A to 1.35 A). The below table provides the primary and secondary peaks of pertinent crystalline phases for material characterization purposes.

| Phase | Primary Peak | Secondary Peak |
|---|---|---|
| Yttria (Y₂O₃) | [2 2 2] @ d = 3.061 Å | [4 4 0] @ d = 1.874 Å |
| | (measured at 3.062 Å) | (measured at 1.875 Å) |
| Alumina (Al₂O₃) | [1 0 4] @ d = 2.551 Å | [1 1 6] @ d = 1.602 Å |
| | (measured at 2.552 Å) | (measured at 1.602 Å) |
| Yttrium zirconate | [1 1 1] @ d = 3.003 Å | [2 2 0] @ d = 1.839 Å |
| (YZ, Y₄Zr₃O₁₂) | (measured at d = 3.007 Å) | (measured at d = 1.841 Å) |
| Yttrium aluminum | [1 2 1] @ d = 2.615 Å | [2 0 2] @ d = 1.855 Å |
| perovskite | (measured at 2.614 Å) | (measured at 1.856 Å) |
| (YAP, YAlO₃) | | |
| Yttrium aluminum | [4 2 0] @ d = 2.684 Å | [6 4 0] @ 1.664 Å |
| garnet | (measured at d = 2.683 Å) | (measured at d = 1.664 Å) |
| (YAG, Y₃A₁₅O₁₂) | | |
| Yttrium aluminum | [1 2 2] @ d = 3.014 Å | [0 3 2] @ d = 2.915 Å |
| monoclinic | (measured at 3.019 Å) | (measured at 2.914 Å) |
| (YAM, Y₄Al₂O₉) | | |

The below standards should be used to determine material properties of the polycrystalline materials described herein.
Density should be measured in accordance with ASTM C373-18.
Grain size should be measured in accordance with ASTM E112-13 (2021).
Modulus of rupture (MOR) should be measured in accordance with C1161-18, wherein the test bars are fabricated to the “Type B Configuration,” with a bar thickness (A) of 4 mm and a bar width (B) of 3 mm. A minimum of 5 bars are used for the test.
Plane strain (K_{IC}) fracture toughness should be measured using a “notched beam” method with a bar thickness (A) of 4 mm and a bar width (B) of 3 mm. A minimum of 5 bars are used for the test. The test bars are notched to mid-thickness (T/2) (2 mm in depth in this configuration) using a diamond wafer blade with a notch width of width of 0.010+/−0.002 inch. Each sample bar is positioned on a one-inch (1″) support span consisting of a ball and rod support system, with the notch being centered below a 0.125 inch (⅛″) loading ball with the notch facing down (away from the loading ball). The bar is loaded in an Instron test frame until failure. The actual bar thickness and width is measured near the break. The solid thickness at the break is measured in three locations and averaged. K_{IC} fracture toughness values are calculated for each bar using load at failure and geometric data. The average K_{IC} fracture toughness of the at least five specimens is used for the final reported K_{IC} fracture toughness value.
Dielectric constant and loss tangent testing should be conducted by evaluation of the dominant TE01 (transverse electric) Resonant Mode. Such evaluation methods are described, for instance, in the following NIST (National Institute of Standards and Technology) Technical Note:
   Janezic, Michael D., N. Paulter, and J. Blendell. “Dielectric and conductor-loss characterization and measurements on electronic packaging materials,” NIST Technical note 1520 (2001), available online at: https://doi.org/10.6028/NIST.TN.1520.
Etch rate is to be measured by lapping the samples with stages of sequentially smaller diamond abrasives, followed by polishing on a Sn-composite lapping plate with a diamond slurry, followed by performing a carbon tetrafluoride (CF4) etch for 10 hours, wherein the gas rate ios set at 50 sccm at 5.0 Pa and the upper plate and lower plate RF power is set at 135 W (13.56 MHz) and 10 W (13.56 MHz) respectively, resulting in an expected ion energy of less than 200 eV, with all samples etched at the same time, when possible. Etch rates are calculated from differential step height measurements taken via diamond stylus profilometry between plasma exposed and masked portions of the sample surface.
   vii. Miscellaneous

These and other aspects, advantages, and novel features of this new technology are set forth in part in the descriptions and figures herein and will become apparent to those skilled in the art upon examination of the descriptions and figures herein, or may be learned by practicing one or more embodiments of the technology provided for by the present disclosure.

Among those benefits and improvements that have been disclosed, other objects and advantages of this invention will become apparent from the descriptions and figures herein. Detailed embodiments of the present invention are disclosed herein; however, it is to be understood that the disclosed embodiments are merely illustrative of the invention that may be embodied in various forms. In addition, each of the examples given in connection with the various embodiments of the invention is intended to be illustrative, and not restrictive.

Throughout the specification and claims, the following terms take the meanings explicitly associated herein, unless the context clearly dictates otherwise. The phrases “in one embodiment” and “in some embodiments” as used herein do not necessarily refer to the same embodiment(s), though they may. Furthermore, the phrases “in another embodiment” and “in some other embodiments” as used herein do not necessarily refer to a different embodiment, although they may. Thus, various embodiments of the invention may be readily combined, without departing from the scope or spirit of the invention.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references, unless the context clearly dictates otherwise. The meaning of “in” includes “in” and “on”, unless the context clearly dictates otherwise.

While a number of embodiments of the present invention have been described, it is understood that these embodiments are illustrative only, and not restrictive, and that many modifications may become apparent to those of ordinary skill in the art. Further still, unless the context clearly requires otherwise, the various steps may be carried out in any desired order, and any applicable steps may be added and/or eliminated.

### BRIEF DESCRIPTION OF THE DRAWINGS

FIG. 1 illustrates one embodiment of a method for producing polycrystalline materials having tailored amounts of YAP and YZ phases.

FIG. 2 illustrates one embodiment of a method for producing a precursor powder.

FIG. 3 illustrates embodiments for introducing zirconium into the precursor powder to facilitate production of a final powder having YZ phase.

FIGS. 4-6 are graphs illustrating crystalline phases as a function of temperature for various Example 1 materials.

FIG. 7 is an SEM micrograph of a YAP/YAG final product of Example 2.

FIG. 8 is an SEM micrograph of a YAP/YAG/YZ final product of Example 2.

FIG. 9 is a backscattered SEM micrograph of a YAP/YAG/YZ final product of Example 2.

FIG. 10a is a photograph illustrating the bulk (monolithic) final parts of Example 2.

FIG. 10b is a photograph illustrating a white, translucent final part of Example 2 having YZ phase.

FIGS. 11a-11f are graphs illustrating various properties of the Example 1 alloys.

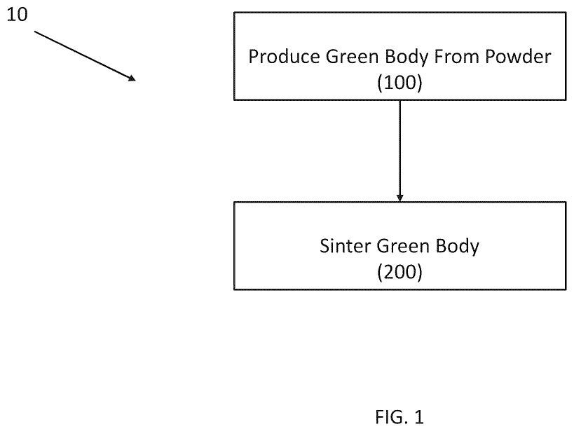

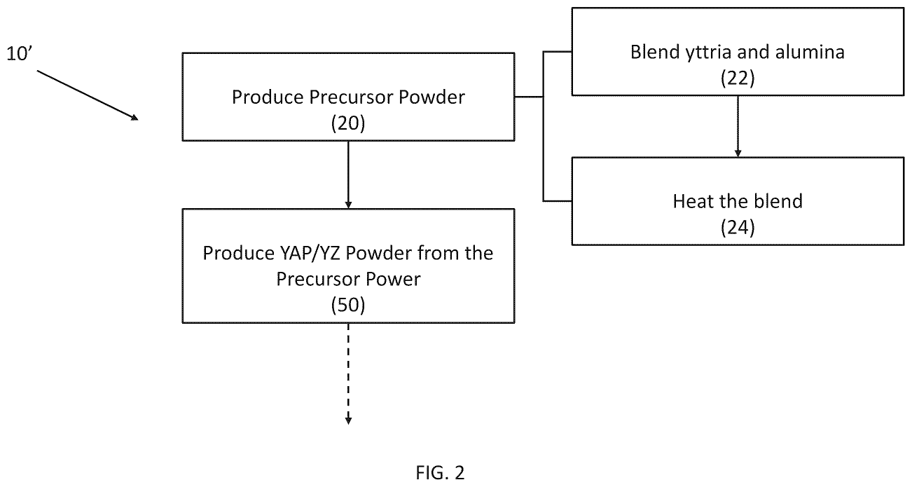

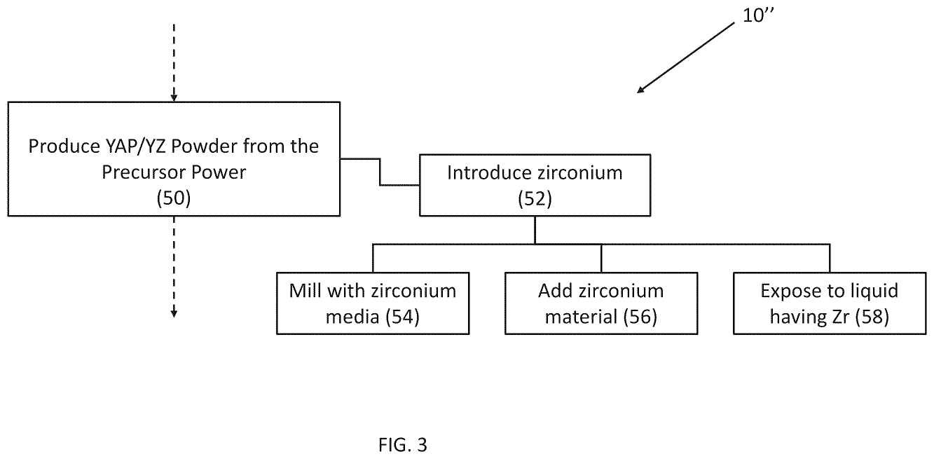

### DETAILED DESCRIPTION

### Example 1—Formulation and Calcination of Starting Materials

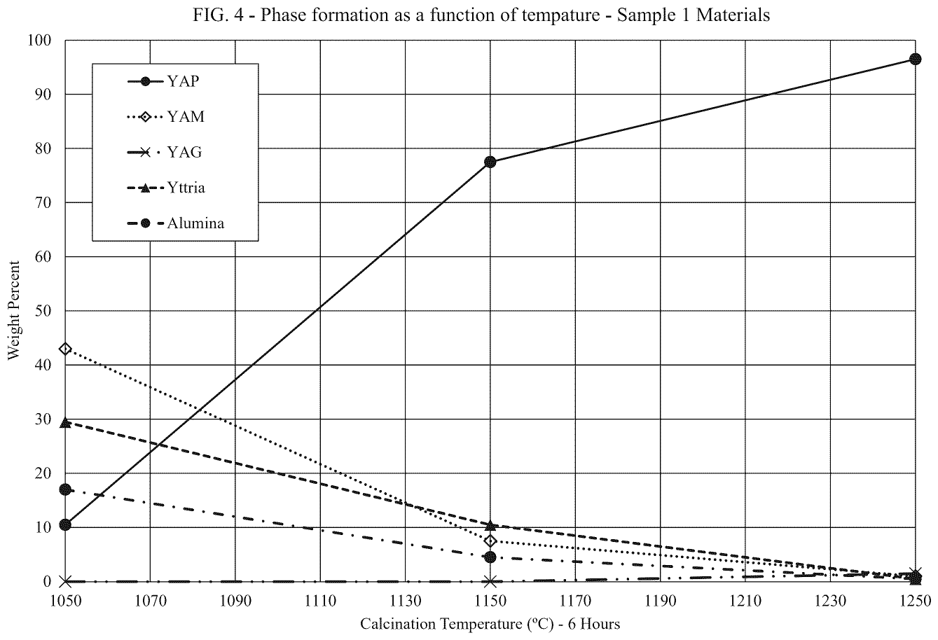

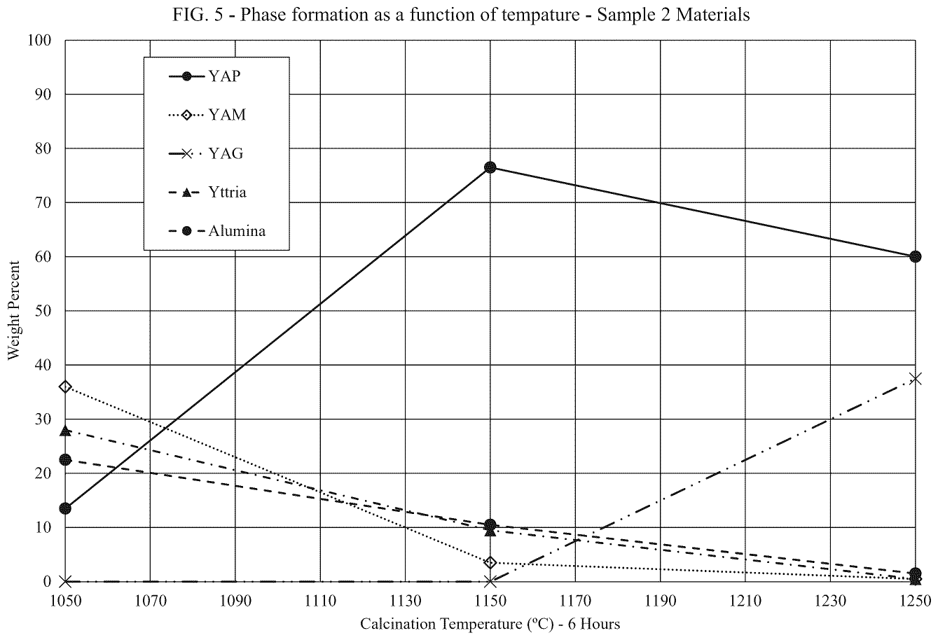

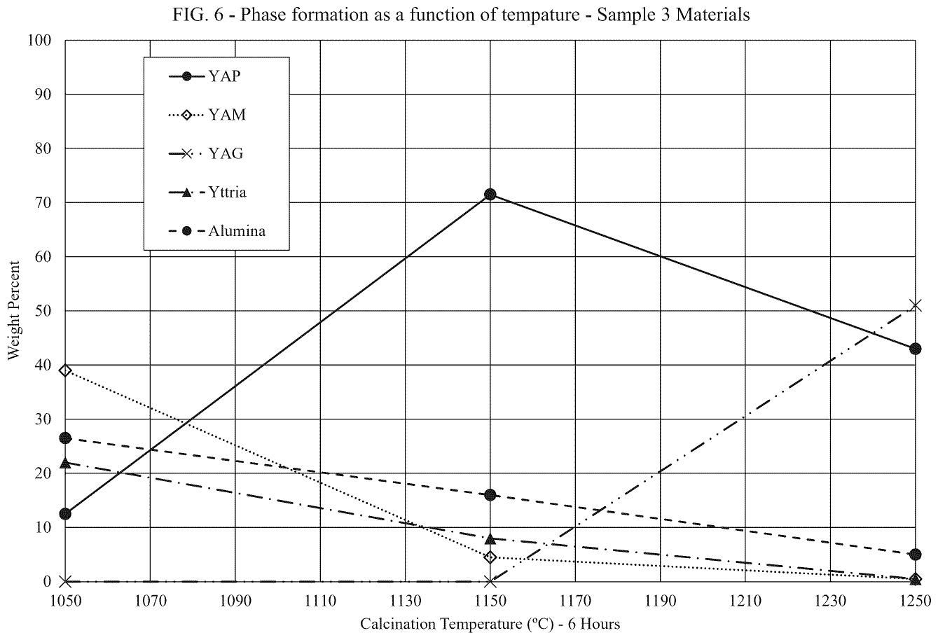

High purity yttria (Y₂O₃) and alumina (Al₂O₃) were blended to produce a series of powders having from 45-50 mol. % yttria and 50-55 mol. % alumina. The formulated powders were subsequently calcined at various temperatures for 6 hours. The crystalline phases of the calcined samples were then determined using X-ray diffraction (XRD) as a function of composition and calcination time. (Material characterization methods are defined in Section vi of the Summary of the Disclosure of this patent application.) The results are shown in Tables 1-3, below, and in FIGS. 4-6.

TABLE 1
XRD Analysis of Sample 1 Materials (in weight percent)

| Calcination | YAP | YAM | YAG | Yttria | Alumina |
|---|---|---|---|---|---|
| Temp (° C.) | (YAlO₃) | (Y₄Al₂O₉) | (Y₃Al₅O₁₂) | (Y₂O₃) | (Al₂O₃) |
| 1050 | 10.5 | 43 | 0 | 29.5 | 17 |
| 1150 | 77.5 | 7.5 | 0 | 10.5 | 4.5 |
| 1250 | 96.5 | 1 | 1.5 | 0.5 | 0.5 |

TABLE 2
XRD Analysis of Sample 2 Materials (in weight percent)

| Calcination | YAP | YAM | YAG | Yttria | Alumina |
|---|---|---|---|---|---|
| Temp (° C.) | (YAlO₃) | (Y₄Al₂O₉) | (Y₃Al₅O₁₂) | (Y₂O₃) | (Al₂O₃) |
| 1050 | 13.5 | 36 | 0 | 28 | 22.5 |
| 1150 | 76.5 | 3.5 | 0 | 9.5 | 10.5 |
| 1250 | 60 | 0.5 | 37.5 | 0.5 | 1.5 |

TABLE 3
XRD Analysis of Sample 3 Materials (in weight percent)

| Calcination | YAP | YAM | YAG | Yttria | Alumina |
|---|---|---|---|---|---|
| Temp (° C.) | (YAlO₃) | (Y₄Al₂O₉) | (Y₃Al₅O₁₂) | (Y₂O₃) | (Al₂O₃) |
| 1050 | 12.5 | 39 | 0 | 22 | 26.5 |
| 1150 | 71.5 | 4.5 | 0 | 8 | 16 |
| 1250 | 43 | 0.5 | 51 | 0.5 | 5 |

As shown, tailored amounts of YAP (YAlO₃), YAM (Y₄Al₂O₉), YAG (Y₃Al₅O₁₂), yttria and alumina phases may be produced using predetermined amounts of yttria and alumina and preselected calcining conditions. Accordingly, materials having preselected crystalline phase structures may be produced. For example, as shown in Table 1, to produce a material having a high weight fraction of YAP phase (e.g., ≥95 wt. % YAP), about a 50:50 molar ratio of yttria:alumina may be preselected and then calcined a temperature of 1250° C. As another example, about a 45:50 molar ratio of yttria:alumina may be preselected and then calcined at a temperature of 1250° C. to produce a bulk material having about 60 wt. % YAP phase or about 38% YAG phase. Many other combinations may be preselected and achieved, as the data shows.

### Example 2—Post-Calcination Processing and Firing of Starting Materials

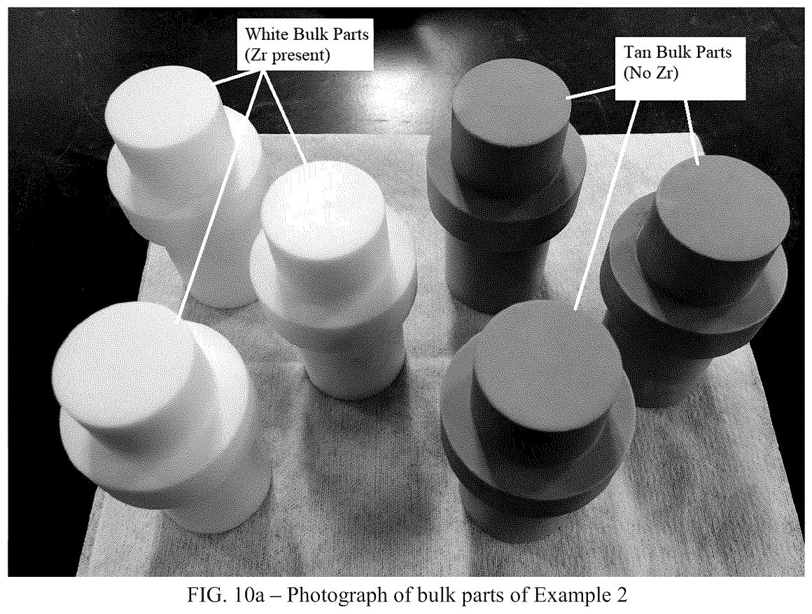

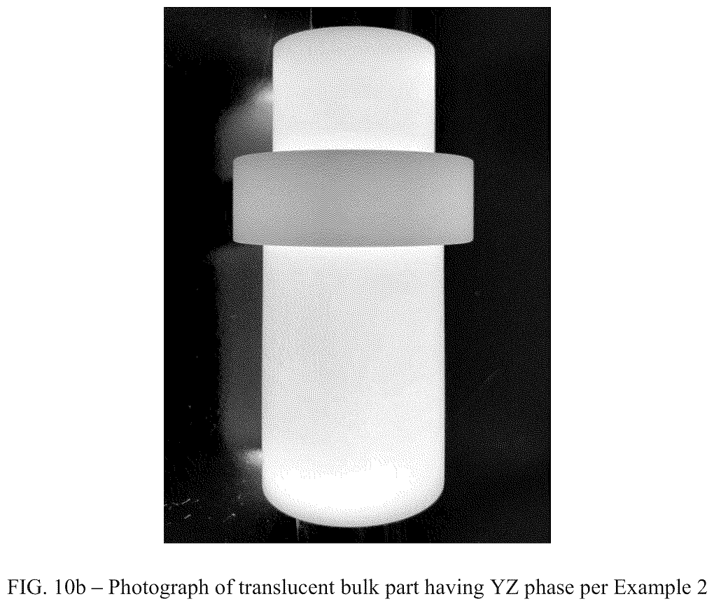

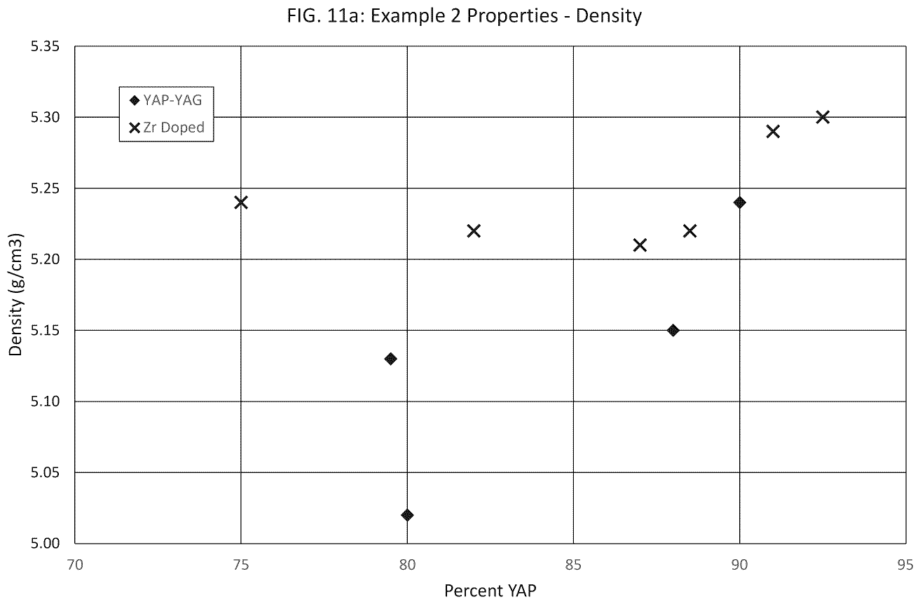

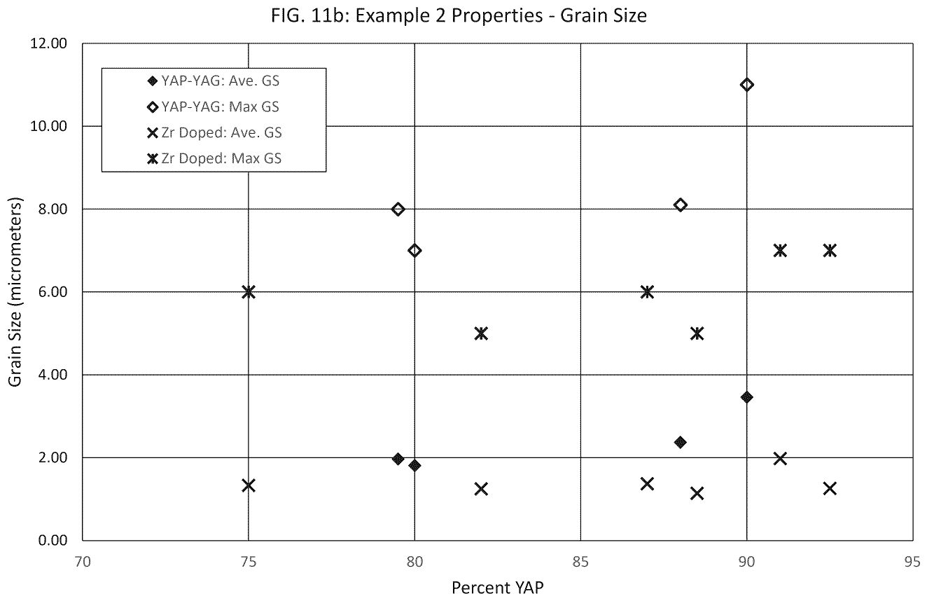

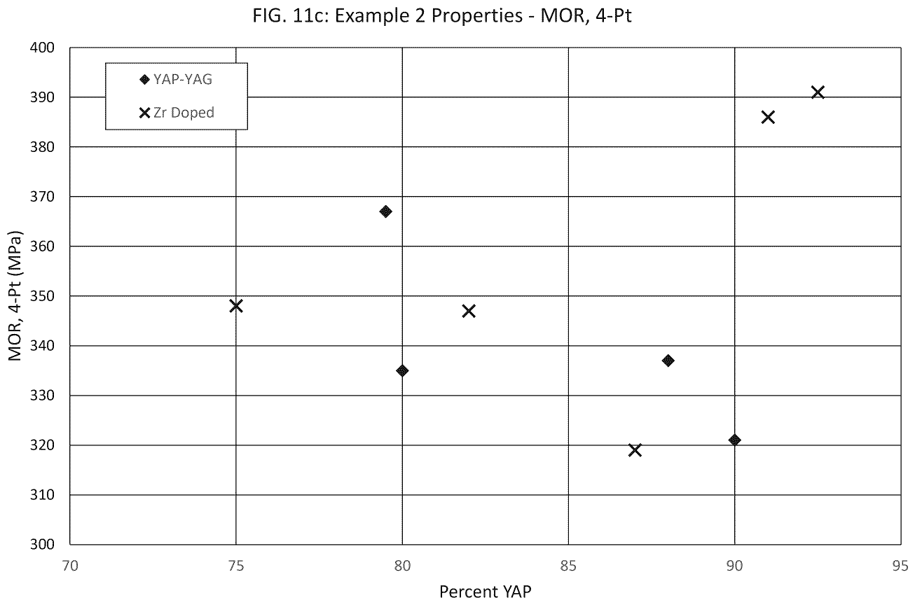

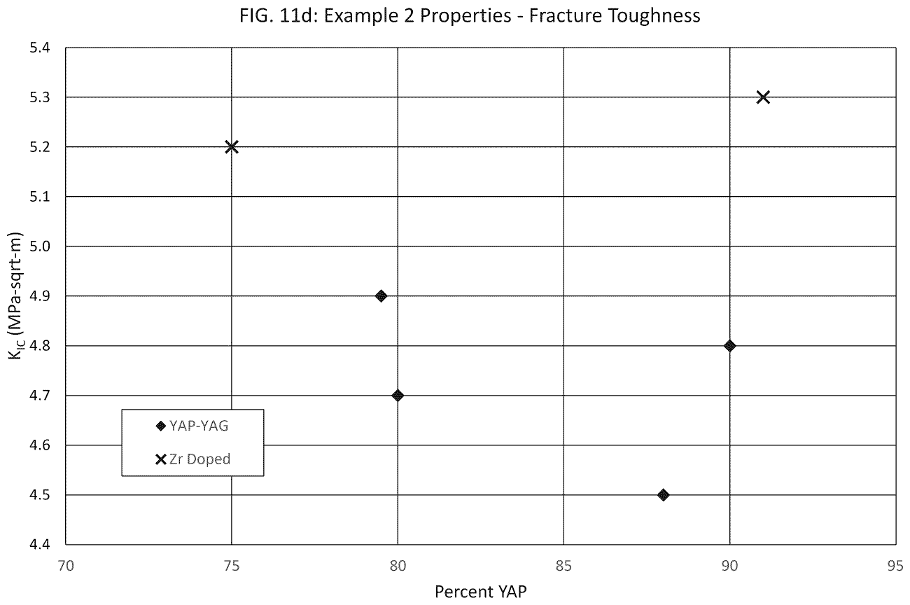

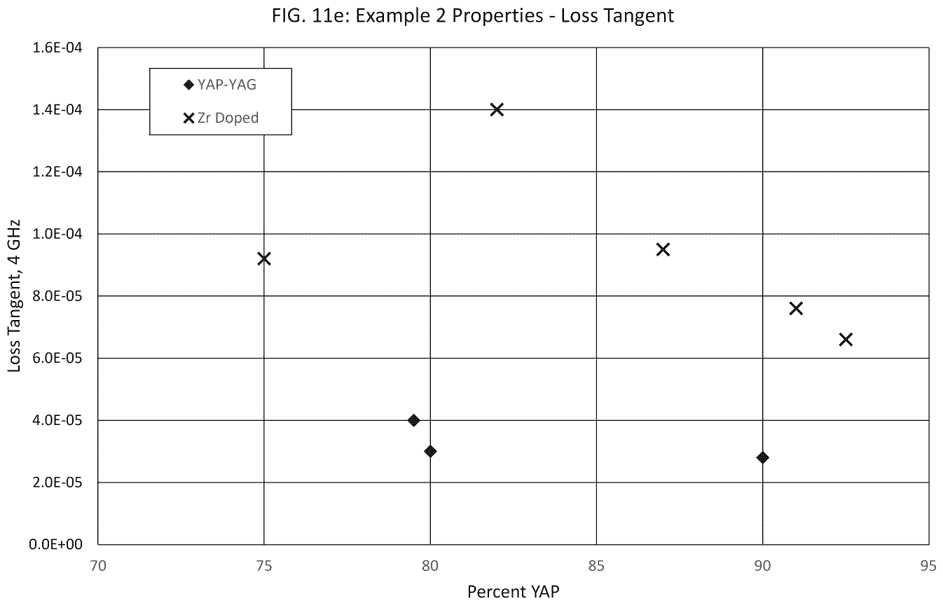

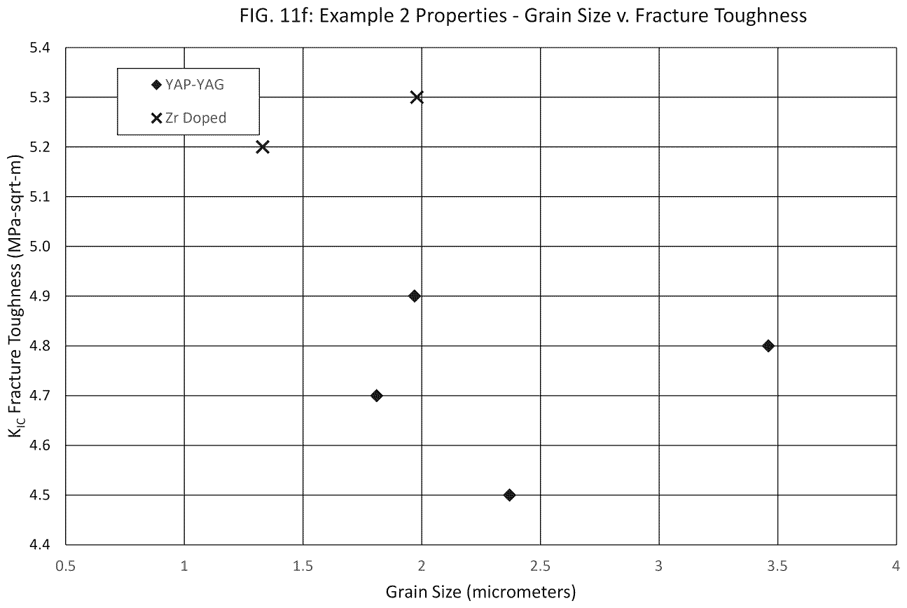

Several powders were produced as per Example 1. Those powers were selected to have a high weight fraction of YAG phase. Several powders (batches 1.1-1.4) were attrition milled using alumina as the milling media while several other powders (batches 2.1-2.6) were attrition milled using zirconia (ZrO₂) as the milling media. For batch number 2.4, additional zirconia particles (approximately 0.5 wt. %) were added during milling to achieve the target zirconium content. The powders were then screened at 500 mesh, blended with an appropriate organic binder and then spray dried. The powders were then made into bulk parts by filling molds, then dry pressing to form a solid compact, and then sintering at about 1650° C. for 4-6 hours. After sintering, various properties of the bulk parts were measured/characterized, the results of which are shown in Tables 4-5, below. (Material characterization methods are defined in Section vi of the Summary of the Disclosure of this patent application.) Photographs of representative bulk parts are shown in FIGS. 10a-10b. Various graphs illustrating the properties of the Example 1 materials are provided in FIGS. 11a-11f.

For comparison purposes, a bulk part was made from a conventional pure yttria powder in generally the same manner as described above. This bulk material was white, realized a density of 4.95 g/cm³, an average grain size of 3.0 micrometers, a maximum grain size of about 15 micrometers, a MOR (4-pt, MPa) of 130 MPa, a K_{IC} fracture toughness of 1.2 MPa m^{1/2}, a dielectric constant (4 GHz) of 11.5, and a loss tangent (4 GHz) of 2.5×10⁻⁵.

TABLE 4
XRD Analysis of Example 2 Bulk Materials (in weight percent)

| Batch No. | 1.1 | 1.2 | 1.3 | 1.4 | 2.1 | 2.2 | 2.3 | 2.4 | 2.5 | 2.6 |
|---|---|---|---|---|---|---|---|---|---|---|
| Percent YAP | 80 | 90 | 88 | 79.5 | 91 | 75 | 87.0 | 82.0 | 88.5 | 92.5 |
| (YAlO₃) | | | | | | | | | | |
| Percent YAG | 20 | 10 | 12 | 20.5 | 8 | 23.5 | 11.0 | 14.5 | 10.5 | 6.5 |
| (Y₃Al₅O₁₂) | | | | | | | | | | |
| Percent YZ | 0 | 0 | 0 | 0 | 1 | 1.5 | 2.0 | 3.0 | 1.0 | 1 |
| (Y₄Zr₃O₁₂) | | | | | | | | | | |

TABLE 5
Properties of Example 2 Bulk Materials

| Part No. | 1.1 | 1.2 | 1.3 | 1.4 | 2.1 | 2.2 | 2.3 | 2.4 | 2.5 | 2.6 |
|---|---|---|---|---|---|---|---|---|---|---|
| Color | Tan | Tan | Tan | Tan | White | White | White | White | White | White |
| Density | 5.02 | 5.24 | 5.15 | 5.13 | 5.29 | 5.24 | 5.21 | 5.22 | 5.22 | 5.30 |
| (g/cm³) | | | | | | | | | | |
| Grain Size | 1.81 | 3.46 | 2.37 | 1.97 | 1.98 | 1.33 | 1.37 | 1.25 | 1.14 | 1.26 |
| (Avg - μm) | | | | | | | | | | |
| Grain Size | 7 | 11 | 8.1 | 8 | 7 | 6 | 6 | 5 | 5 | 7 |
| (Max. - μm) | | | | | | | | | | |
| MOR, 4-pt. | 335 | 321 | 337 | 367 | 386 | 348 | 319 | 347 | — | 391 |
| (MPa) | | | | | | | | | | |
| Toughness, | 4.7 | 4.8 | 4.5 | 4.9 | 5.3 | 5.2 | — | — | — | — |
| K_{IC} (MPa | | | | | | | | | | |
| m^{1/2}) | | | | | | | | | | |
| Dielectric | — | — | — | 15.1 | 14.8 | 15.5 | — | — | — | — |
| Strength, | | | | | | | | | | |
| 1 mm (AC) | | | | | | | | | | |
| (KV/mm) | | | | | | | | | | |
| Dielectric | 14.1 | 15.4 | — | 15.0 | 15.7 | 14.8 | 15.5 | 15.3 | — | 15.6 |
| Constant, | | | | | | | | | | |
| 4 GHz | | | | | | | | | | |
| Loss | 3.0 × | 2.8 × | — | 4.0 × | 7.6 × | 9.2 × | 9.5 × | 1.4 × | — | 6.6 × |
| Tangent, | 10⁻⁵ | 10⁻⁵ | | 10⁻⁵ | 10⁻⁵ | 10⁻⁵ | 10⁻⁵ | 10⁻⁴ | | 10⁻⁵ |
| 4 GHz | | | | | | | | | | |

### Phase Differences Between Alumina and Zirconia Milled Powders

As shown in Table 4, different phases may be achieved by using alumina or zirconia milling media, or by addition of zirconia particles to the powder. Products made from the alumina milled powders resulted in bulk products (1.1-1.4) consisting essentially of YAP and YAG phases. Products made from the zirconia milled powders resulted in bulk products (2.1-2.6) having YAP and YAG phases, but also measurable amounts of Y₄Zr₃O₁₂ (YZ) phase. The production of the YZ phase is the result of zirconium transferred to the formulation during attrition milling. As shown by batch/part no. 2.4, YZ phase may also be achieved by addition of zirconium-containing materials (e.g., zirconia) to the bulk powders. As described in further detail below, the addition of zirconium may impart beneficial properties. Zirconium may be introduced to produce YZ phase by, for instance, using zirconium-containing milling media and/or by direct addition of zirconium materials (e.g., zirconia) to the powder blend. Organic or aqueous solutions comprising zirconium may also be used to introduce zirconium.

### Density

As Table 5 shows, high densities were achieved. Considering the theoretical densities of YAP and YAG phases have been reported at 5.35 and 4.55 g/cc, respectively, the measured density values are exceptionally high.

### Microstructure and Grain Size

As Table 5 shows, the average grain sizes are small and repeatable. The maximum grain sizes are likewise small.

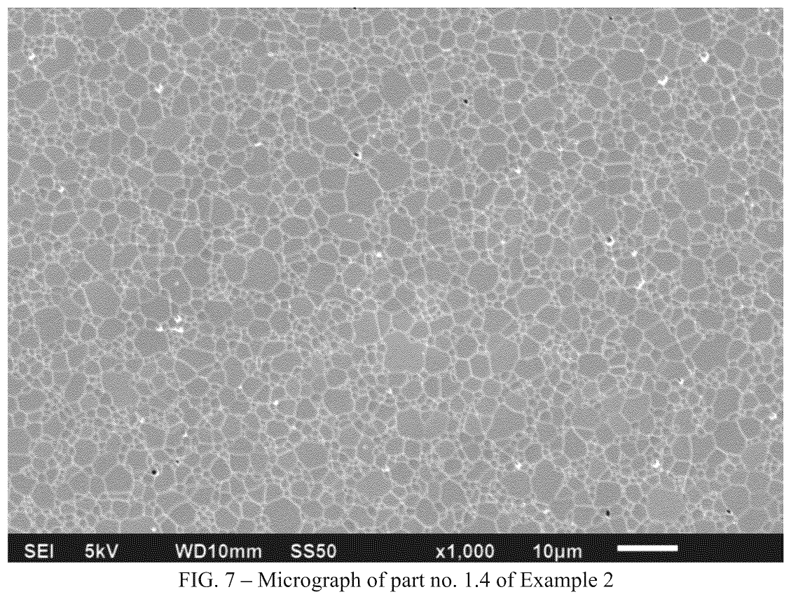

FIG. 7 is a micrograph of bulk part no. 1.4 (79.5% YAP and 20.5% YAG phases by weight). As shown, the grain size is uniform and generally homogenous. The absence of porosity is notable, confirming the measured density is near the theoretical maximum. There is also an absence of intragranular porosity. The small amount of porosity that does exist appears to be intergranular-located along the grain boundaries. Enhanced mechanical and/or corrosion resistance properties may, therefore, be realized.

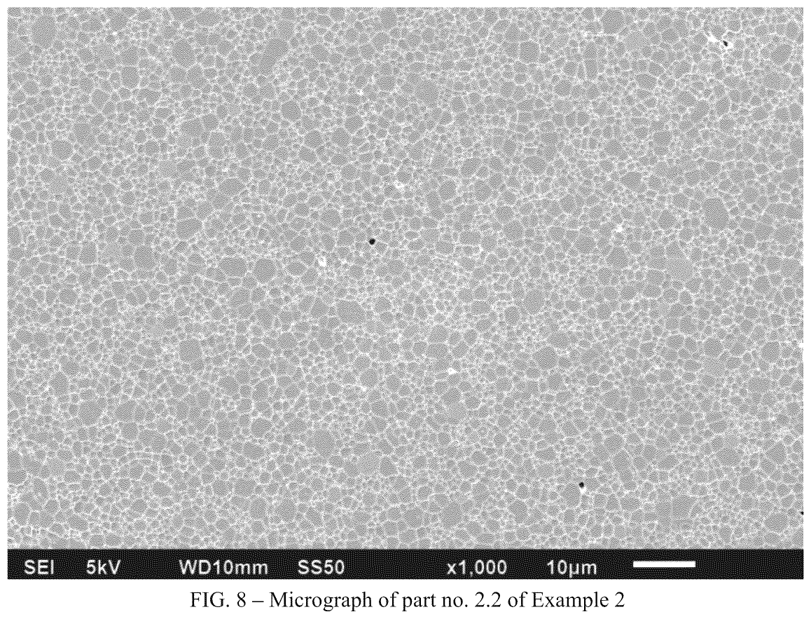

FIG. 8 is an SEM micrograph of bulk part no. 2.1 (75% YAP, 23.5% YAG and 1.5% YZ phases by weight). The weight ratio of YAP/YAG is similar to that of bulk part no. 1.4 shown in FIG. 7, but with 1.5 wt. % YZ phase. Without being bound by theory, it is believed that the presence of the YZ phase likely contributes to reduced grain size and increased uniformity. At sintering temperatures (e.g., about 1650° C.), the zirconium may be in solid solution with the yttria. Upon cooling, YZ phase precipitates at the grain boundaries, thereby depleting some yttria from the system and shifting the YAP/YAG ratio slightly closer to YAG.

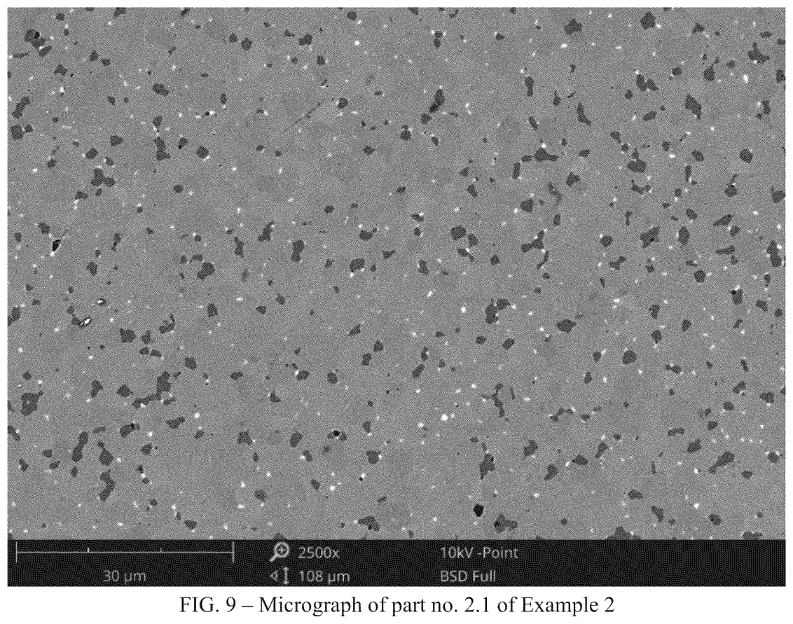

FIG. 9 is backscattered SEM micrograph of bulk part no. 2.1 (91% YAP, 8% YAG and 1% YZ phases by weight), and illustrates the physical nature of the YZ precipitate phases. The dark phase is YAG, the grey phase is YAP and the small white regions are the YZ precipitates.

### MOR (Modulus of Rupture) and Fracture Toughness

As Table 5 shows, dramatic improvements in mechanical properties were realized for the bulk parts as compared to pure YAG phase and pure yttria phase. The 4-point flexural strength (MOR) of the yttria phase and the YAG phase is approximately 100 to 150 MPa, and both materials generally realize low fracture toughness, typically about 1.2 MPa*m^{1/2}, as confirmed by the comparative data for the bulk yttria product, provided above.

Conversely, the inventive materials realize a high MOR (321-386 MPa), which is similar to that of high purity alumina (>300 MPa). The inventive materials also realize exceptionally high fracture toughness (4.5-5.3 MPa*m^{1/2}). Indeed, bulk part no. 2.1 (91% YAP, 8% YAG, 1% YZ phases by weight) was measured to have a 4-point flexural strength of 386 MPa and a fracture toughness of 5.3 MPa·m^{1/2}. These mechanical property improvements offer significant advantages in component design and application as well as in processing that requires diamond grinding/machining procedures.

### Dielectric Properties

The inventive materials show very good dielectric performance. Pure yttria has a dielectric constant and loss tangent of approximately 11.5 and 2×10⁻⁵, respectively, as confirmed by the comparative data for the bulk yttria product, provided above. The inventive materials realized dielectric constants in the range of 14 to 16 with loss tangents ranging from 3×10⁻⁵ to 8×10⁻⁵. Pure YAP phase is reported to have a dielectric constant above 15, while pure YAG phase is reported to have a dielectric constant of about 11.7. The dielectric constant variation shown by the compositions of Example 2 is derived from the relative content of YAG and YAP phases.

### Color

Another interesting result was the color of the bulk products made from the zirconia milled powders. As shown in FIG. 10a, products made from the alumina milled powders (materials 1.1-1.4) are tan (light brown) in color. Surprisingly, the YZ-containing materials (2.1-2.6), however, realize a brilliant white color. The YZ-containing materials are also translucent (FIG. 10b). Thus, in addition to potentially providing enhanced physical properties, YZ-containing materials may also provide products with an enhanced visual appearance.

### Example 3—Evaluation of Plasma Etch Resistance

An additional coupon was made from the powder of material 2.1 of Example 2. Comparative coupons were made from aluminum oxide (99.5% and 99.8% purity) and yttrium oxide. The samples were then prepared for plasma etch testing by lapping with stages of sequentially smaller diamond abrasives and finally polished on a Sn-composite lapping plate with a diamond slurry. After lapping, surface roughness measurements were taken with a Zeiss LSM 800 scanning laser confocal microscope over 700×700 μm areas, with the areal surface texture calculations performed following ISO 25178, the results of which are provided in Table 6, below.

Next, a carbon tetrafluoride (CF4) etch was performed for 10 hours. The gas rate was set at 50 sccm at 5.0 Pa. Upper and lower plate RF power was set at 135 W (13.56 MHz) and 10 W (13.56 MHz) respectively, resulting in an expected ion energy of less than 200 eV. All material samples were etched at the same time, minimizing any possible differences in etch conditions. Etch rates were calculated from differential step height measurements taken via diamond stylus profilometry, between plasma exposed and masked portions of the sample surface. The etch rate results are also shown in Table 6, below.

TABLE 6
Properties of Example 3 Materials

| | | Average | Average | Bulk |
|---|---|---|---|---|
| | Density | Grain Size | Roughness, | Etch Rate |
| Material | (g/cm3) | (μm) | Sa (μm) | (μm/hr) |
| Al₂O₃ (99.5%) | 3.92 | 3.12 | 0.030 | 0.08 |
| Al₂O₃ (99.8%) | 3.97 | 1.80 | 0.019 | 0.08 |
| Y₂O₃ | 4.96 | 2.11 | 0.025 | 0.01 |
| YAP (Ex. 2, | 5.30 | 1.56 | 0.025 | 0.01 |
| Sample 2.1) | | | | |

As shown, sample 2.1 from Example 2 realizes lower surface roughness as compared to the comparative materials. Sample 2.1 from Example 2 also realizes higher density and lower grain size as compared to the comparative materials. Sample 2.1 also realizes much better plasma etch resistance as compared to the comparative alumina materials. Sample 2.1 realizes a comparable etch rate to the comparative yttria material, but with much better mechanical properties.

While various embodiments of the present disclosure have been described in detail, it is apparent that modifications and adaptations of those embodiments will occur to those skilled in the art. However, it is to be expressly understood that such modifications and adaptations are within the spirit and scope of the present disclosure.

What is claimed is:

1. A polycrystalline material comprising:
(a) at least 50 wt. % yttrium aluminum perovskite (YAP) phase; and
(b) at least 0.1 wt. % yttrium zirconate (YZ) phase.

2. The polycrystalline material of claim 1 comprising from 0.2 wt. % to 10 wt. % YZ phase.

3. The polycrystalline material of claim 1, comprising at least 95 wt. % YAP phase.

4. The polycrystalline material of claim 1, comprising 0.1-49.9 wt. % yttrium aluminum garnet (YAG) phase.

5. The polycrystalline material of claim 1, comprising not greater than 10 wt. % yttria phase.

6. The polycrystalline material of claim 1, comprising not greater than 10 wt. % alumina phase.

7. The polycrystalline material of claim 1, wherein the polycrystalline material realizes a density of at least 4.5 g/cm³.

8. The polycrystalline material of claim 1, wherein the polycrystalline material realizes an average grain size of not greater than 30 micrometers and a maximum grain size of not greater than 80 micrometers.

9. The polycrystalline material of claim 1, wherein the polycrystalline material is in the form of a semiconductor component.

10. The polycrystalline material of claim 9, wherein the semiconductor component is in the form of a nozzle blank or a nozzle.

11. A method for producing the polycrystalline material, comprising:
(a) producing a green body from a first powder comprising yttrium aluminum perovskite (YAlO₃) and yttrium zirconate (YZ) phases;
(b) sintering the green body at a temperature of from 1200° to 1900° C., thereby forming a final product, wherein the final product comprises:
(a) at least 50 wt. % of the yttrium aluminum perovskite (YAP) phase; and
(b) at least 0.1 wt. % the yttrium zirconate (YZ) phase.

12. The method of claim 11, comprising:
prior to the producing a green body step, preparing a precursor powder, wherein the preparing the precursor powder step comprises:
(i) blending yttria and alumina to prepare a powder blend, wherein the powder blend comprises from 45-50 mol. % yttria and 50-55 mol. % alumina;
(ii) heating the powder blend at a temperature and for a time sufficient to produce the precursor powder, wherein the precursor powder comprises at least 50 wt. % YAP phase, not greater than 10 wt. % yttria phase, and not greater than 10 wt. % alumina phase; and
producing the first powder from the precursor powder.

13. The method of claim 12, wherein the precursor powder comprises not greater than 9 wt. % yttria phase.

14. The method of claim 12, wherein the precursor powder comprises not greater than 9 wt. % alumina phase.

15. The method of claim 12, wherein the precursor powder comprises at least 90 wt. % YAP phase.

16. The method of claim 12, wherein the precursor powder comprises not greater than 20 wt. % YAM phase (Y₄Al₂O₉) and not greater than 50 wt. % YAG phase (Y₄Al₂O₉).

17. The method of claim 16, wherein the precursor powder comprises at least 0.5 wt. % YAG (Y₃Al₅O₁₂) phase, or at least 1 wt. % YAG phase, or both.

18. The method of claim 11, wherein the sintering comprises pressureless sintering.

19. The method of claim 11, wherein the step of producing the first powder from the precursor powder comprises:
introducing zirconium into the precursor powder.

20. The method of claim 19, wherein the introducing step comprises adding a zirconium-containing powder to the precursor powder.
